(19) United States
(12) Patent Application Publication
(10) Pub. No.: US 2006/0183293 A1
(43) Pub. Date: Aug. 17, 2006

(54) Method of forming alignment mark and method of manufacturing semiconductor device

(75) Inventor: Suguru SASAKI, Tokyo (JP)

Correspondence Address: STEVEN ROBERTS;SHINJYU GLOBAL IP, SOUTH FOREST BLDG., 11TH FLOOR, 1-4-19, MINAMIMORI-MACHI, KITA-KU, OSAKA, 530-0054, JP

(73) Assignee: OKI ELECTRIC INDUSTRY CO., LTD., Tokyo (JP)

(21) Appl. No.: 11/276,116

(22) Filed: Feb. 15, 2006

(30) Foreign Application Priority Data
Feb. 15, 2005 (JP) 2005/037588

(51) Int. Cl. H01L 21/44

(52) U.S. Cl. 438/401; 438/675; 438/685

(57) ABSTRACT

A method of forming an alignment mark for specifying an optimum exposing position includes the steps of: preparing a substrate having a semiconductor element and an insulation film covering the semiconductor element; forming a resist pattern having a first opening on the insulation film, the first opening having a first width which is 1.25 times or less than a second width of a contact plug; forming a second opening with the first width in the insulation film; removing the resist pattern; forming a first conductive film on the insulation film and inside the second opening; and removing the first conductive film on the insulation film while leaving a portion of the first conductive film inside the second opening as an alignment mark.

### BACKGROUND OF THE INVENTION

1. Field of the Invention

The present invention relates to a method of manufacturing a semiconductor device as well as a method of forming an alignment mark in a process of manufacturing a semiconductor device, which in particular is used for a positioning aligner.

2. Background Information

With respect to a conventional semiconductor integrated circuit, a structure in which the lower layer and the upper layer are electrically connected using a tungsten plug has been applied most commonly.

This tungsten plug as conventionally used is formed through following processes. First, a first silicon oxide film (SiO₂ film) is formed on a foundation substrate, after which a resist pattern is formed on the first silicon oxide film using a predetermined pattern as a mask. Next, in order to expose the foundation substrate, an opening is formed in the first silicon oxide film by etching the first silicon oxide film while using the resist pattern as a mask. Next, using a CVD (chemical vapor deposition) method or another type of deposition method, a tungsten film is formed on the entire surface of the foundation substrate where the resist pattern and the opening are formed. Thereby, a plug (hereinafter to be referred to as a tungsten plug) for connecting metal patterns formed in the upper layer and the lower layer which sandwich the first silicon oxide film is formed inside the opening.

Next, a tungsten film is etched over the first silicon oxide film while leaving the tungsten plug inside the opening intact. Then, an inter-layer insulation film, e.g. a silicon oxide film, is formed on the first silicon oxide film.

Next, a second silicon oxide film, a silicon nitride film, and a third silicon oxide film are formed sequentially on the first silicon oxide film. Thereby, a laminated structure including the first silicon oxide film, the second silicon oxide film, the silicon nitride film, and the third silicon oxide film is formed on the foundation substrate. Then, in the latter processes, the tungsten plug is exposed by forming an opening in the laminated structure of the second silicon oxide film, the silicon nitride film, and the third silicon oxide film, after which a metal pattern which electrically connects with the tungsten plug via the opening is formed. In this process, however, in order to align with the tungsten plug having a predetermined pattern, it is necessary to form the opening and the metal pattern so that the metal pattern overlaps the opening.

For example, one method for enabling the tungsten plug and the opening to overlap would have a process to form a predetermined pattern in the first silicon oxide film over the foundation substrate by which an optimum overlapping position is specified (cf. Japanese Laid Open Patent Application No. 7-249558 (hereinafter to be referred to as Patent Reference 1), Japanese Laid Open Patent Application No. 8-298237 (hereinafter to be referred to as Patent Reference 2) and Japanese Laid Open Patent Application No. 2004-39731 (hereinafter to be referred to as Patent Reference 3)). Such process is usually referred to as an alignment process.

There are two types of commonly used alignment processes. One alignment process (the first method) specifies the optimum overlapping position using the image recognition of the predetermined pattern (hereinafter to be referred to as alignment mark) formed in the first silicon oxide film. The other alignment process (the second method) specifies the optimum overlapping position by detecting the diffraction light which is generated by irradiating a laser beam to the alignment mark.

In the first method, normally, a resist pattern with a line type or a slit type (which will also be referred to as a line and space type) is used in etching the first silicon oxide film to form the alignment mark. When using a slit type resist pattern, for instance, the first silicon oxide film is etched on the basis of this resist pattern, after which tungsten is filled therein to form an alignment mark having a convex and line shape. In the second method, normally, a resist pattern with a dot type or a hole type is used in etching the first silicon oxide film to form the alignment mark. When using a hole type resist pattern, for instance, the first silicon oxide film is etched on the basis of this resist pattern, after which tungsten is filled therein to form a convex alignment mark.

Generally, the line type or slit type resist pattern has a structure in which several to dozens of convex or canaliform line patterns are aligned regularly at some micrometer intervals. Each convex or canaliform line patterns has a length of 50 to 100 μm and a width of 1 to 6 μm. Generally, the dot type or hole type resist pattern has a structure in which several to dozens of square or circular patterns are aligned regularly in two dimension at some micrometer intervals. A length of a side of the square pattern and a diameter of the circular pattern are about 4 μm.

However, when manufacturing a semiconductor device using such alignment marks as described above, the metal, e.g. tungsten (i.e. tungsten plug) which is filled into the trenches formed based on the resist pattern, can be oxidized which results in an increase in volume. As the volume of the tungsten plug increases due to oxidation, the layer formed on the tungsten plug may receive more stress and may possibly be damaged.

Specifically, this problem is caused because when the upper portion of the tungsten plug 103a formed in the trench 103 of the alignment mark is etched at the time of removing the tungsten film, which was formed at the same time when the tungsten plug was formed, a trench 110a is formed at the etched portion, as shown in FIG. 1A. If the second silicon oxidation film 104 is formed over the etched surface, as described above, a gap 110b will be formed between the tungsten plug 103a and the second silicon oxide film 104, as shown in FIG. 1B.

There is a possibility that air will be contained in the gap 110b formed between the tungsten plug 103b and the second silicon oxide film 104. In that case, if, for instance, oxygen atoms (O) are contained in the air, the oxygen atoms will react to the tungsten (W), which will result in the production of a tungsten oxide such as WO₃ or W₂O₅. Normally, tungsten will increase in volume when it is oxidized. Accordingly, as shown in FIG. 1C, the oxidized tungsten pushes up the second silicon oxide film 104 formed in the upper layer while applying stress to the second silicon oxide film 104, and the silicon nitride film 105 and the third silicon oxide film 106 formed in the other upper layers. Such stress may cause cracks to be produced in each layer.

Such a problem often occurs when manufacturing a semiconductor device having a ferroelectric capacitor including a ferroelectric film as a capacity insulator made of metal and oxygen elements. This is because, in such case, it is necessary to anneal (heat-treat) the semiconductor wafer in the oxygen atmosphere at a high temperature around 600 to 800° C. in order to recover from the damage that the ferroelectric film received when the ferroelectric film was patterned into the shape of capacitor through etching or when the capacitor electrodes were formed through sputtering. Without such annealing process, the ferroelectric capacitors might not be able to operate normally due to the damage that the ferroelectric film received.

When conducting such high-temperature annealing process in an oxygen atmosphere, the semiconductor wafer will be heated while a large number of oxygen atoms are contained in the gap 110b. Accordingly, a comparatively large portion of the tungsten (O) may be oxidized easily, which may result in an increase in the amount of expansion of the tungsten plug 103b. Therefore, the layer formed on the tungsten plug 103a, e.g. the second silicon oxide film 104 etc., can receive greater stress due to the expansion of the tungsten plug 103a, and thus there is greater possibility that it may be damaged.

Due to the conditions as described above, according to the conventional methods of manufacturing a semiconductor device, the process margin at the time of forming the alignment mark will tend to become narrow. This process margin is particularly one which is used in forming the contact (e.g. tungsten plug), which is for electrically connecting the upper and lower layers, and the metal pattern (e.g. tungsten plug), which is to be used as an alignment mark, at the same time, or in more concrete terms, a process margin that is required for the etching conditions and time span in removing the metal film (e.g. tungsten film) which is formed as a result of depositing metals (e.g. tungsten) to form the contact (e.g. tungsten plug). Because of such narrow process margin, in the conventional manufacturing methods, there is less controllability in the manufacturing processes, which should be recognized as a problem.

In view of the above, it will be apparent to those skilled in the art from this disclosure that there exists a need for an improved method forming an alignment mark and a method of manufacturing a semiconductor device which applies such improved method of forming an alignment mark. This invention addresses this need in the art as well as other needs, which will become apparent to those skilled in the art from this disclosure.

### SUMMARY OF THE INVENTION

It is therefore an object of the present invention to resolve the above-described problems and to provide a method of forming an alignment mark which is capable of producing an expanded process margin at the time of forming an alignment mark so that the process precision required in manufacturing a semiconductor device can be relaxed, and a method of manufacturing a semiconductor device which applies such method of forming an alignment mark.

In accordance with one aspect of the present invention, a method of forming an alignment mark for specifying an optimum exposing position includes the steps of: preparing a substrate having a semiconductor element and an insulation film covering the semiconductor element; forming a resist pattern having a first opening on the insulation film, the first opening having a first width which is 1.25 times or less than a second width of a contact plug which is electrically connected to the semiconductor element; forming a second opening with the first width in the insulation film by etching the insulation film using the resist pattern as a mask; removing the resist pattern; forming a first conductive film on the insulation film and inside the second opening by depositing a metal over the insulation film; and removing the first conductive film on the insulation film while leaving a portion of the first conductive film inside the second opening as an alignment mark.

In accordance with another aspect of the present invention, a method of manufacturing a semiconductor device includes the steps of: preparing a substrate having a semiconductor element and an insulation film covering the semiconductor element; forming a resist pattern having a first opening on the insulation film, the first opening having a first width which is 1.25 times or less than the second width of a contact plug which is electrically connected to the semiconductor element; forming a second opening with the first width in the insulation film by etching the insulation film using the resist pattern as a mask; removing the resist pattern; forming a first conductive film on the insulation film and inside the second opening by depositing a metal over the insulating film; and removing the first conductive film on the insulation film while leaving a portion of the first conductive film inside the second opening as an alignment mark.

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1A, FIG. 1B and FIG. 1C are diagrams illustrating possible problems that could occur by using an alignment mark formed according to the conventional technology;

FIG. 2A is an overhead view of a resist pattern according to a first embodiment of the present invention, the resist pattern being for use in forming an alignment mark according to the first embodiment of the present invention;

FIG. 2B is a sectional view of the resist pattern according to the first embodiment of the present invention taken along a line I-I′ shown in FIG. 2A;

FIG. 3A is an overhead view showing a structure of an alignment mark according to the first embodiment of the present invention;

FIG. 3B is a sectional view of the alignment mark according to the first embodiment of the present invention taken along a line II-II′ shown in FIG. 3A;

FIG. 4A to FIG. 5B are diagrams showing processes of forming the alignment mark in a method of manufacturing a semiconductor device according to the first embodiment of the present invention;

FIG. 6 is a photograph of a semiconductor substrate having alignment marks 3a-1 and 3a-2 which satisfy a condition of d≦1.25 s according to the first embodiment of the present invention;

FIG. 7 is a photograph of a semiconductor substrate having alignment marks 103a-1 and 103a-2 which do not satisfy the condition of d≦1.25 s according to the first embodiment of the present invention;

FIG. 8A is an overhead view of a resist pattern according to a second embodiment of the present invention, the resist pattern being for use in forming an alignment mark according to the second embodiment of the present invention;

FIG. 8B is a sectional view of the resist pattern according to the second embodiment of the present invention taken along a line III-III′ shown in FIG. 8A;

FIG. 9A is a overhead view showing a structure of an alignment mark according to the second embodiment of the present invention;

FIG. 9B is a sectional view of the alignment mark according to the second embodiment of the present invention taken along a line IV-IV′ shown in FIG. 9A;

FIG. 10 is a graph showing an intensity spectrum of diffraction light generated by irradiating a laser beam to the alignment mark according to the second embodiment of the present invention;

FIG. 11 is a photograph of a semiconductor substrate having an alignment mark 123a-1 which does not satisfy a condition of d≦1.25 s according to the second embodiment of the present invention and an alignment mark 23a-1 which satisfies this condition; and

FIG. 12 is a photograph of a semiconductor substrate having an alignment mark 23a-2 which satisfies the condition of d≦1.25 s according to the second embodiment of the present invention.

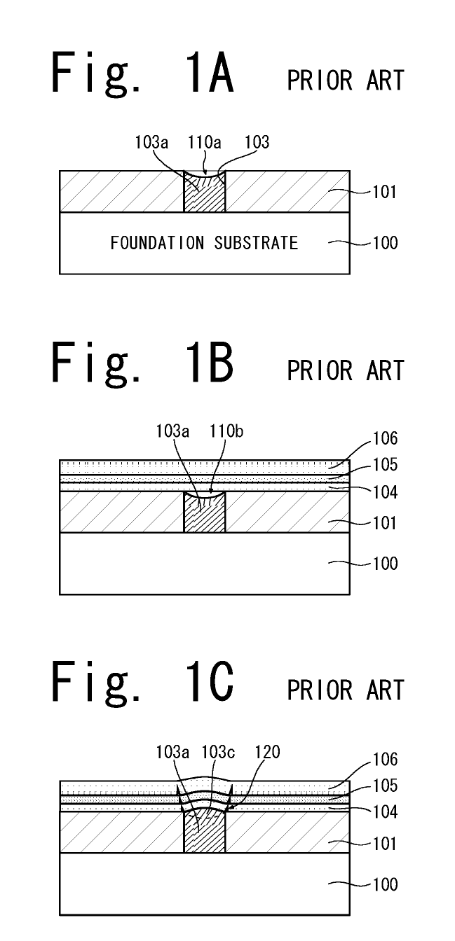

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

Now, a first embodiment of the present invention will be described in detail with reference to the drawings.

(Structure)

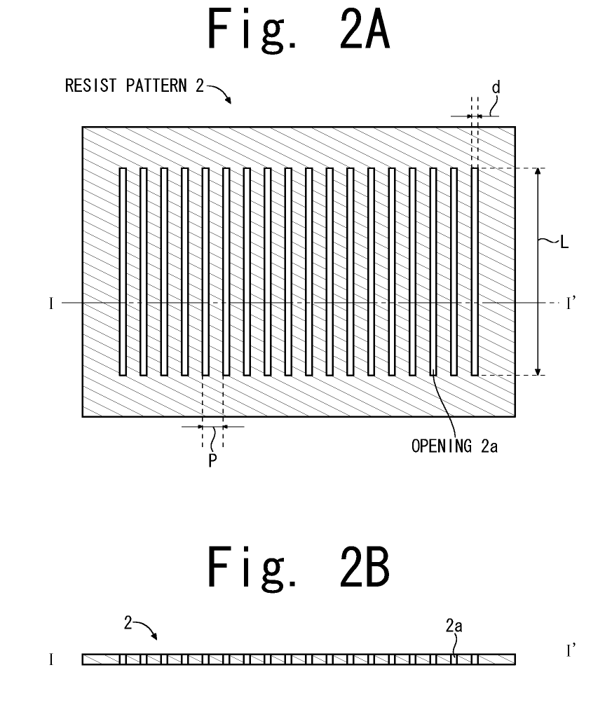

In this embodiment, a slit type resist pattern 2 as shown in FIG. 2A and FIG. 2B is used to form an alignment mark. FIG. 2A shows an overhead view of the resist pattern 2, and FIG. 2B is a sectional view of the resist pattern 2 taken along a line I-I′ shown in FIG. 2A.

As shown in FIG. 2A and FIG. 2B, the slit type resist pattern 2 of this embodiment has multiple long and thin canaliform openings 2a. Each opening 2a has a width of d and a length of L. The openings 2a are disposed at predetermined intervals P, and they penetrate through the top and bottom surfaces of the resist pattern 2.

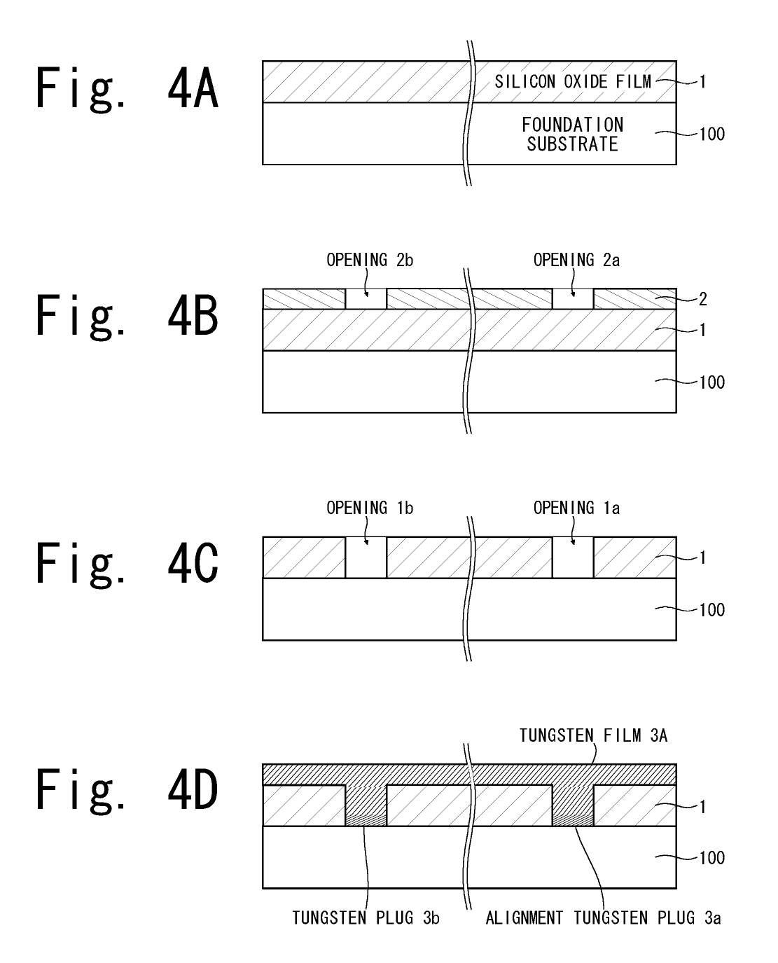

In this embodiment, provided that the size of a device pattern (hereinafter, to be referred to as device size) is s, the width d of the trench of each opening 2a is set to be no greater than 1.25 times the size of the device pattern. The size of the device pattern, for instance, is the size of a plug (e.g. a length of a short side of the plug) for connecting the upper and lower layers (which corresponds to a tungsten plug 3b shown in FIG. 4D to be mentioned later on). For example, if the device size s is 0.64 μm, the width d of the opening 2a should be no greater than 0.8 μm. Moreover, for example, if the device size s is 0.4 μm, the width d of the opening 2a should be no greater than 0.48 μm. At this point, in order to secure a larger process margin, it is preferred that the width d of the opening 2a is set to a value which is 1.2 times smaller than the device size s. The lower limit of the width d should be a limit value of resolution in image recognition, or the lower limit should be decided by factors such as acceptable values in relation to the manufacturing process. Here, the lower limit of the width d, for instance, can be set to 0.4 μm.

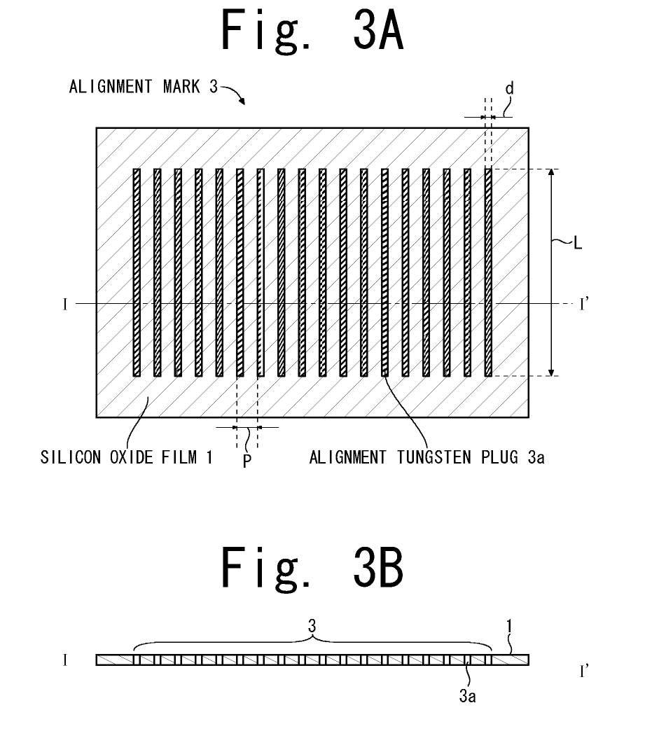

Here, the length L of the opening 2a can be set to 70 μm for instance, and the predetermined interval P of the adjacent openings 2a can be set to 20 μm for instance. However, the present invention is not limited to these values, and variations can be made to them according to factors such as the light intensity of a lighting system, the resolution of an imaging device, and so forth. With respect to the depth of the opening 2a, i.e. the film thickness of the resist pattern 2, it is appropriate as long as it is a sufficient thickness by which the lower layer, which corresponds to a silicon oxide film 1 shown in FIGS. 3A and 3B, can be etched effectively.

For instance, such resist pattern 2 as described above is formed on the silicon oxide film 1 (q.v. FIGS. 3A and 3B) which is formed on a foundation substrate 100 in which semiconductor elements are formed. An alignment mark 3 of this embodiment is formed inside the silicon oxide film 1 as shown in FIGS. 3A and 3B, by filling in a metal such as tungsten (W) to trenches (which correspond to openings 1a shown in FIG. 4C to be mentioned later on). The trenches of the silicon oxide film 1 are formed by etching the silicon oxide film 1 while using the resist pattern 2 as a mask. FIG. 3A shows an overhead view of the silicon oxide film 1 which serves as an inter-layer insulation film and has the alignment mark 3, and FIG. 3B is a sectional view of the silicon oxide film 1 taken along a line II-II′ shown in FIG. 3A. In the following description, a case in which tungsten is used as a metal in forming the alignment mark will be shown as an example.

Accordingly, as shown in FIGS. 3A and 3B, the alignment mark 3 has a structure in which multiple long and thin convex patterns made of tungsten (i.e. alignment tungsten plugs 3a), each of which has a width of d and a length of L, are aligned in the same way as the openings 2a of the resist pattern 2 (q.v. FIGS. 2A and 2B).

(Manufacturing Method)

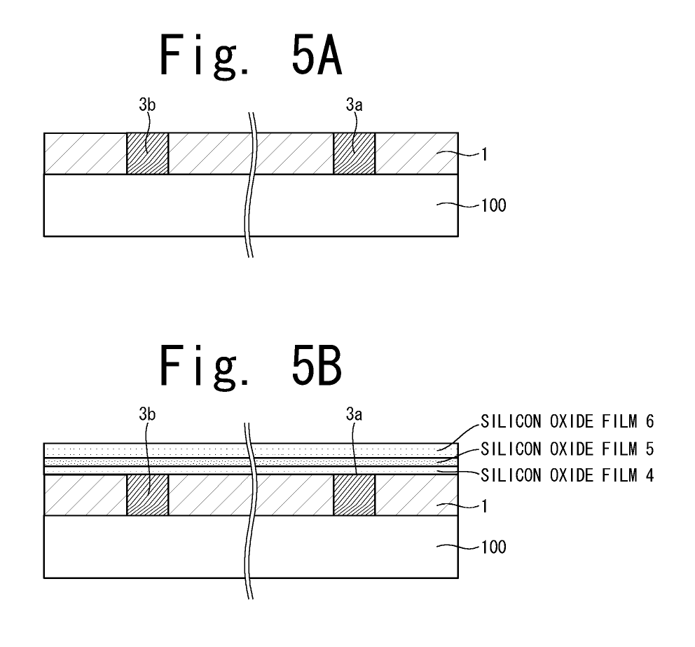

Next, a method of forming a semiconductor device including processes of forming the alignment mark 3 according to this embodiment will be described with reference to the drawings. FIGS. 4A to 5B are diagrams showing a portion of the processes in manufacturing the semiconductor device according to this embodiment.

First, the foundation substrate 100 in which the semiconductor elements are formed is prepared. Then, as shown in FIG. 4A, the silicon oxide film 1 is formed on the upper surface of the foundation substrate 100. For instance, this silicon oxide film 1 can be formed using a CVD (Chemical Vapor Deposition) method, a PVD (Physical Vapor Deposition) method, or a SOG (Spin on Glass) method etc., and its thickness may be 1000 nm (nanometer) for instance.

Next, a resist solution is spin-coated over the surface of the silicon oxide film 1, after which a photolithographic process is conducted to form the resist pattern 2 on the silicon oxide film 1 as shown in FIG. 4B. In addition to the openings 2a as shown in FIGS. 2A and 2B, the resist pattern 2 formed here also has openings 2b. The openings 2b are structures for forming openings 1b (to be described later on) in the silicon oxide film 1. Tungsten (W) will be filled in the openings lb by means of the processes described later, on in order to form tungsten plugs 3b (q.v. FIG. 4B, tungsten plugs are also called contacts) which serve to electrically connect upper and lower layers that sandwich the silicon oxide film 1 in between. Accordingly, the openings 2b are formed on regions of the foundation substrate 100 where the semiconductor elements are formed so that they overlap the electrodes of the semiconductor elements. On the other hand, the openings 2a are formed on the regions of the foundation substrate 100 that lies between the regions where the semiconductor elements are formed (i.e. openings 2a are formed on the grid line). Here, the width d of the opening 2b is set to be no greater than 1.25 times the device size s (e.g. the width of the opening 2b for forming the tungsten plug 3b (q.v. FIGS. 4A and 4B)). Therefore, the alignment mark 3 having the width d which is no greater than 1.25 times the device size s will be formed inside the silicon oxide film 1 as a result of the processes described below.

After the resist pattern 2 is formed as described above, anisotropic etching is conducted on the silicon oxide film 1 using this resist pattern 2 as a mask. As a result, openings 1a and 1b are formed in the silicon oxide film 1 as shown in FIG. 4C.

Next, using a sputtering method or the CVD method, tungsten (W) is deposited on the silicon oxide film 1 and inside the openings 1a and 1b formed in the silicon oxide film 1. In this embodiment, the tungsten is deposited on the silicon oxide film 1 until it reaches a depth of 600 nm or greater. By this process, as shown in FIG. 4D, the tungsten plug 3b is formed inside the opening 1b, the alignment tungsten plug 3a is formed inside the opening 1a, and a tungsten film 3A which is 600 nm thick is formed on the silicon oxide film 1. In addition, here and in the following description, the term “on the silicon oxide film 1” includes the upper surfaces of the tungsten plug 3b and the alignment tungsten plug 3a.

Next, the tungsten film 3A formed on the silicon oxide film 1 is removed by a CMP (Chemical and Mechanical Polishing) method or an etch-back method for instance (q.v. FIG. 5A). Here, when using the CMP method, the tungsten film 3A on the silicon oxide film 1 can be removed by being polished for 2 to 4 hours using a polishing pad and slurry. The polishing pad has a two-layer structure comprising a nonwoven fabric as a base sheet and a polyurethane foam applied on the nonwoven fabric. The slurry includes hydrogen perioxide solution (H₂O₂) as an oxidizing reagent and colloidal silica of which average grain diameter is 0.1 to 0.2 μm as abrasive grains. The abrasive concentration of the slurry is 5 to 6 wt %. At this time, the polishing rate is 0.2˜0.3 μm/min.

On the other hand, when using the etch-back method, RIE (Reactive Ion Etching) using a mixed gas of SF₆ and C1₂ as an etching gas is conducted in removing the tungsten film 3A. At this time, a gas flow rate is set to SF₆:Cl₂=7:3 (sccm) and a pressure inside chamber is set to 5 mTorr. Moreover, RF power is switched in three stages. The RF power is set to 40 W in the first stage, 20 W in the second stage and 5 W in the third stage. Under these conditions, the first stage is conducted for 10 seconds, the second stage is conducted for 80 seconds under EDP (End Point Detection) and the third stage is conducted for 10 seconds. Thereby, the tungsten film 3A can be removed. At this time the etching rate is 450 nm/sec.

In the above described processes of removing the tungsten film 3A, the width d of the alignment tungsten plug 3a, which is formed inside the opening la, is supposed to be no greater than 1.25 times the device size s or preferably no greater than 1.2 times the device size s, and therefore, it is possible to obtain a larger margin in the etching conditions of the tungsten film 3A described above as compared to the conventional cases. This means that it is possible to obtain a larger process margin in the processes of forming the alignment mark. Accordingly, even when some changes are made in the above-described etching conditions, such changes can be dealt with within the process margin, and no trench will be formed in the upper part of the alignment tungsten plug 3a.

After the tungsten film 3A on the silicon oxide film 1 is removed in the above-described manner, a silicon oxide film 4, a silicon nitride film 5 and a silicon oxide film 6 are formed sequentially on the silicon oxide film 1 using the CVD method, PVD method or SOG method etc (q.v. FIG. 5B). The silicon oxide film 4 functions as an adhesion layer for improving adhesion between the upper and lower layers sandwiching the silicon oxide film 4. The silicon oxide film 6 also functions as an adhesion layer for improving adhesion between the upper and lower layers sandwiching the silicon oxide film 6. The silicon nitride film 5 functions as a barrier layer for preventing oxygen atoms (O) from diffusing from the upper layer to the lower layer in the latter processes of manufacturing. The film thickness of these three films can be set to 200 nm, 150 nm and 100 nm, respectively.

Since no trench will be formed on the upper part of the alignment tungsten plug 3a as described above, even when another layer (i.e. silicon oxide film 4 in this description) is formed over the upper part of the alignment tungsten plug 3a, no gap will be formed in between this layer and the alignment tungsten plug 3a. Accordingly, even when conducting heat treatment in an oxygen atmosphere in the later processes, for instance, it is possible to prevent the alignment tungsten plug 3a from being oxidized and increasing its volume. As a result, it becomes possible to prevent the upper layers (i.e. silicon oxide film 4, silicon nitride film 5, silicon oxide film 6 etc.) on the alignment tungsten plug 3a from being cracked.

Furthermore, in the latter processes, when a resist pattern having a predetermined pattern is formed on a multi-layer film including the silicon oxide film 4, the silicon nitride film 5 and the silicon oxide film 6 for instance, an optimum exposing position of the resist pattern is determined by reading out the alignment mark 3 formed as described above using a CCD (Charge Coupled Device) camera and image recognizing the image data obtained thereby. Moreover, in the processes of forming the resist pattern having a predetermined pattern on the multi-layer film, the specified optimum exposing position is used for positioning aligners.

As described above, by setting the width d of the openings 2a, i.e. the width d of the alignment tungsten plugs 3a which form the alignment mark 3, to no greater than 1.25 times the device size s, even when the etching conditions of the tungsten film 3A are changed in forming the alignment mark 3, it is possible to prevent trenches from being formed in the upper parts of the alignment tungsten plugs 3a as the tungsten film 3A is etched in the manufacturing processes. Therefore, even when another layer is formed over the upper parts of the alignment tungsten plugs 3a, no gap will be formed in between this layer and the alignment tungsten plugs 3a. As a result, even when conducting heat treatment in the oxygen atmosphere in the later processes for instance, it is possible to prevent the alignment tungsten plugs 3a from being oxidized and increasing their volume. Accordingly, it becomes possible to prevent the upper layers on the alignment plugs 3a from being cracked.

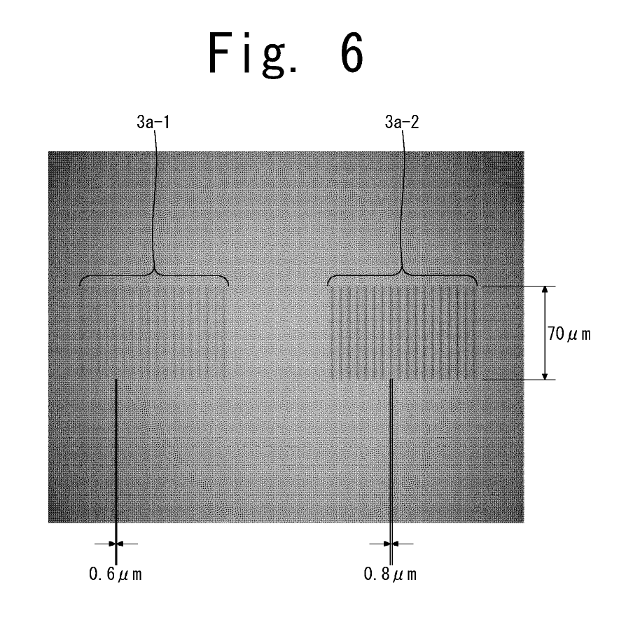

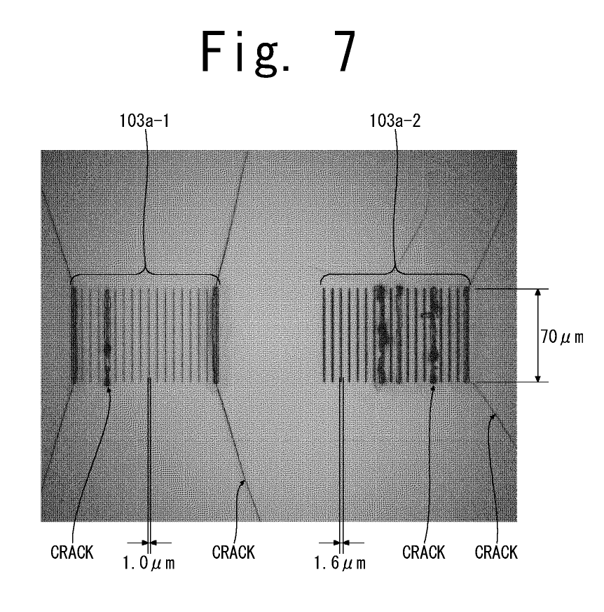

Now, a mechanism of crack development in relation to the width d of the alignment tungsten plugs 3a will be described with reference to the drawings. FIG. 6 is a photograph taken of a semiconductor substrate, in which alignment marks 3a-1 and 3a-2 which satisfy the condition of d≦1.25 s as described in this embodiment are formed, and which was heated at the temperature of 800° C. in the oxygen atmosphere for 30 minutes. FIG. 7 is a photograph taken of a semiconductor substrate, in which alignment marks 103a-1 and 103a-2 which do not satisfy the condition of d≦1.25 s as described in this embodiment are formed, and which was heated at the temperature of 800° C. in the oxygen atmosphere for 30 minutes. In both FIG. 6 and FIG. 7, the device size s is set to be 0.64 μm. In either case, removal of the tungsten film 3A was done using the etch-back method as described above with respect to the manufacturing method, and the conditions of the etch-back process used here are those described above. In FIG. 6, the width d of the alignment mark 3a-1 on the left side is set to be 0.6 μm (i.e. about 0.94 times the device size s), and the width d of the alignment mark 3a-2 on the right side is set to be 0.8 μm (i.e. 1.25 times the device size s). In FIG. 7, the width d of the alignment mark 103a-1 on the left side is set to be 1.0 μm (i.e. about 1.6 times the device size s), and the width d of the alignment mark 103a-2 on the right side is set to be 1.6 μm (i.e. 2.5 times the device size s).

As can be seen from FIG. 6 and FIG. 7, when the width d of the alignment tungsten plug 3a is no greater than 1.25 times the device size s (the case of FIG. 6), no crack is formed on the upper layers (i.e. the silicon oxide film 4, the silicon nitride film 5, and the silicon oxide film 6) of the alignment tungsten plugs 3a in the semiconductor device after being heated in an oxygen atmosphere. In other words, the semiconductor device is formed appropriately. On the other hand, when the width d of the alignment tungsten plug 3a is greater than 1.25 times the device size s (the case of FIG. 7), cracks are formed on the upper layers (i.e. the silicon oxide film 4, the silicon nitride film 5 and the silicon oxide film 6) of the alignment tungsten plugs 3a. Here, it is obvious that there are defects in the semiconductor device.

As described above, according to this embodiment of the present invention, by forming the alignment tungsten plug 3a such that its width d becomes no greater than 1.25 times the device size s, it is possible to manufacture a semiconductor device which does not produce any defects even after the heating treatment in an oxygen atmosphere.

### Second Embodiment

Next, a second embodiment of the present invention will be described in detail with reference to the drawings. In the following, the same reference numbers will be used for the structures that are the same as the first embodiment, and redundant explanations of those structural elements will be omitted.

(Structure)

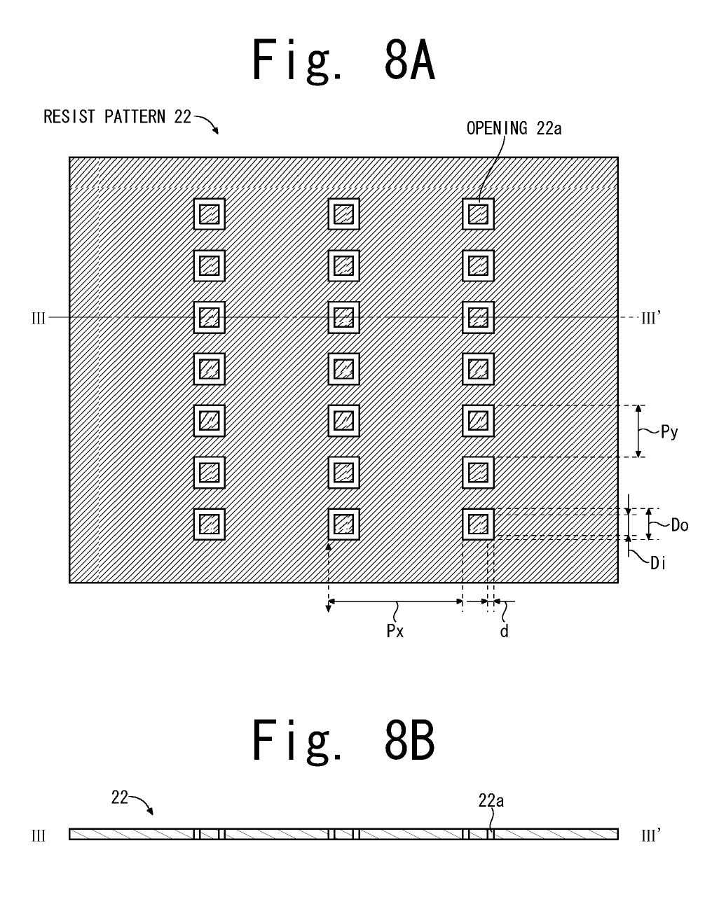

In this embodiment, a framed rectangle type resist pattern 22 as shown in FIG. 8A and FIG. 8B is used to form an alignment mark. FIG. 8A shows a overhead view of the resist pattern 22 and FIG. 8B is a sectional view of the resist pattern 22 taken along a line III-III′ shown in FIG. 8A.

As shown in FIG. 8A and FIG. 8B, the resist pattern 22 of this embodiment has multiple openings 22a each of which has a shape of framed rectangle. The length of an outer circumferential side of each opening 22a is Do and the length of an inner circumferential side of each opening 22a is Di. Accordingly, the width d of a trench forming the opening 22a is (Do-Di)/2 (i.e. d=(Do-Di)/2). The openings 22a are disposed at predetermined intervals in the lengthwise and crosswise directions shown in FIG. 8A. Here, the interval of the lengthwise direction is set to Px and the interval of the crosswise direction is set to Py.

In this embodiment, provided that the size of a device pattern is s as the first embodiment, the width d of trench of each opening 22a is set to be no greater than 1.25 times the size of the device pattern. For example, if the device size s is 0.64 μm, the width d of trench of the opening 22a should be no greater than 0.8 μm. Moreover, for example, if the device size s is 0.4 μm, the width d of trench of the opening 22a should be no greater than 0.48 μm. At this point, in order to secure a larger process margin, it is preferred that the width d of the trench of the opening 22a is set to a value which is 1.2 times smaller than the device size s. The lower limit of the width d should be a limit value of resolution in image recognition, or the lower limit should be decided by factors such as acceptable values in relation to the manufacturing process. Here, the lower limit of the width d, for instance, can be set to 0.4 μm.

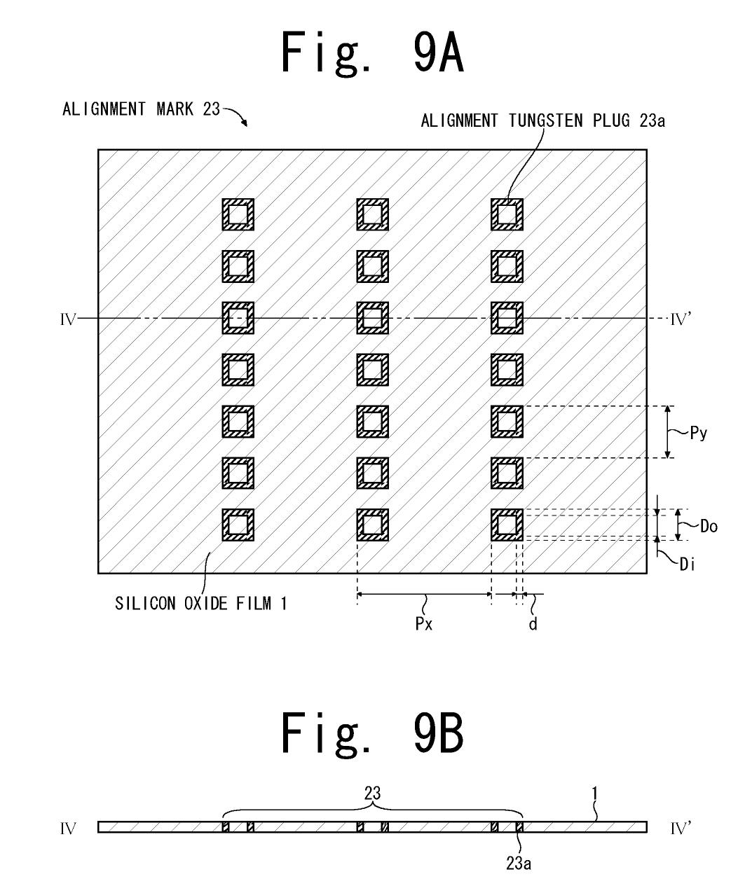

Here, the length Do of the outer circumferential side of the opening 22a can be set to 0.6 μm for instance, and the predetermined interval Px of the adjacent openings 22a in the lengthwise direction can be set to 20 μm for instance. However, the present invention is not limited to these values, and variations can be made to them according to the factors such as the light intensity of a lighting system, the resolution of an imaging device and so forth. The predetermined interval Py of the adjacent openings 22a in the crosswise direction is not limited specified, and can be changed in various ways in the present invention. With respect to the depth of the opening 22a, i.e. the film thickness of the resist pattern 22, it is appropriate as long as it is a sufficient thickness by which the lower layer, which corresponds to a silicon oxide film 1 shown in FIGS. 9A and 9B, can be etched effectively.

As in the case of the first embodiment, for instance, such resist pattern 22 as described above is formed on the silicon oxide film 1 (q.v. FIGS. 9A and 9B) which is formed on a foundation substrate 100 in which semiconductor elements are formed. An alignment mark 23 of this embodiment is formed inside the silicon oxide film 1 as shown in FIGS. 9A and 9B, by filling in a metal such as tungsten (W) to trenches. The trenches of the silicon oxide film 1 are formed by etching the silicon oxide film 1 while using the resist pattern 22 as a mask. FIG. 9A shows an overhead view of the silicon oxide film 1 which serves as an inter-layer insulation film and has the alignment mark 23, and FIG. 9B is a sectional view of the silicon oxide film 1 taken along a line IV-IV′ shown in FIG. 9A. In the following description, as the first embodiment, the use of tungsten as a metal in forming the alignment mark will be shown as an example.

Accordingly, as shown in FIGS. 9A and 9B, the alignment mark 23 has a structure in which multiple framed rectangle patterns made of tungsten (i.e. alignment tungsten plugs 23a), each of which has a shape of a framed rectangle, are aligned in the same way as the openings 22a of the resist pattern 22 (q.v. FIGS. 8A and 8B).

(Manufacturing Method)

A method of forming a semiconductor device including processes of forming the alignment mark 23 according to this embodiment is the same as the first embodiment of the present invention, and redundant explanations of this manufacturing method will be omitted.

Since no trench will be formed on the upper part of the alignment tungsten plug 23a as described above, even when another layer (i.e. silicon oxide film 4 in this description) is formed over the upper part of the alignment tungsten plug 23a, as first embodiment, no gap will be formed in between this layer and the alignment tungsten plug 23a. Accordingly, even when conducting heat treatment in the oxygen atmosphere in the later processes for instance, it is possible to prevent the alignment tungsten plug 23a from being oxidized and increasing its volume. As a result, it becomes possible to prevent the upper layers (i.e. silicon oxide film 4, silicon nitride film 5, silicon oxide film 6 etc.) on the alignment tungsten plug 23a from being cracked.

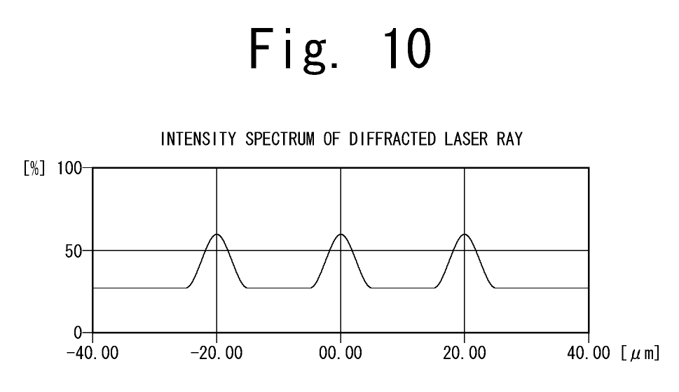

Furthermore, in the latter processes, when a resist pattern having a predetermined pattern is formed on a multi-layer film including the silicon oxide film 4, the silicon nitride film 5, and the silicon oxide film 6, for instance, an optimum exposing position of the resist pattern is specified by irradiating a laser beam to the alignment mark 23 formed as described above and detecting the diffraction light generated thereby. Assuming that the length Do of each outer circumferential side of the alignment tungsten plugs 23a is 4.7 μm and the width of each alignment tungsten plugs 23a is 0.7 μm, for instance, if a laser beam having a wave length of 632.8 nm is irradiated to the alignment mark 23 using He—Ne laser equipment, an intensity spectrum of the diffraction light generate thereby can be obtain as shown in FIG. 10. In FIG. 10, the vertical axis shows the intensity (%) of the diffraction light with respect to the intensity of the irradiated laser beam, and the horizontal axis shows the distance (μm) of the diffraction light from the light axis of the laser beam in the detecting equipment.

In the processes of forming the resist pattern having a predetermined pattern on the multi-layer film, the optimum exposing position of the resist pattern is specified using the results detected as described above, and the specified optimum exposing position is used for positioning aligners.

As described above, by setting the width d of the openings 22a, i.e. the width d of the alignment tungsten plugs 23a which form the alignment mark 23, to no greater than 1.25 times the device size s, even when the etching conditions of the tungsten film (which is the same as the tungsten film 3A in the first embodiment) are changed in forming the alignment mark 23, it is possible to prevent trenches from being formed in the upper portions of the alignment tungsten plugs 23a as the tungsten film 3A is etched in the manufacturing processes. Therefore, even when another layer is formed over the upper portions of the alignment tungsten plugs 23a, no gap will be formed in between this layer and the alignment tungsten plugs 23a. As a result, even when conducting heat treatment in an oxygen atmosphere in the later processes for instance, it is possible to prevent the alignment tungsten plugs 23a from being oxidized and increasing their volume. Accordingly, it becomes possible to prevent the upper layers on the alignment plugs 23a from being cracked.

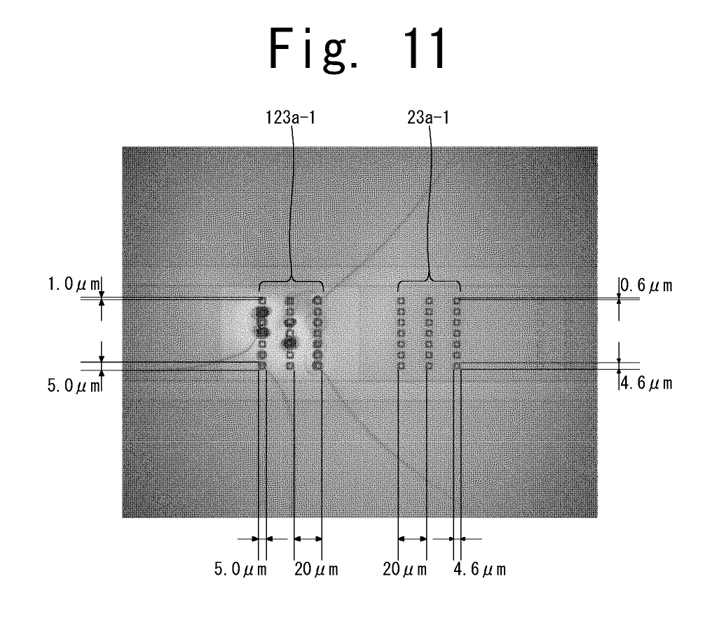

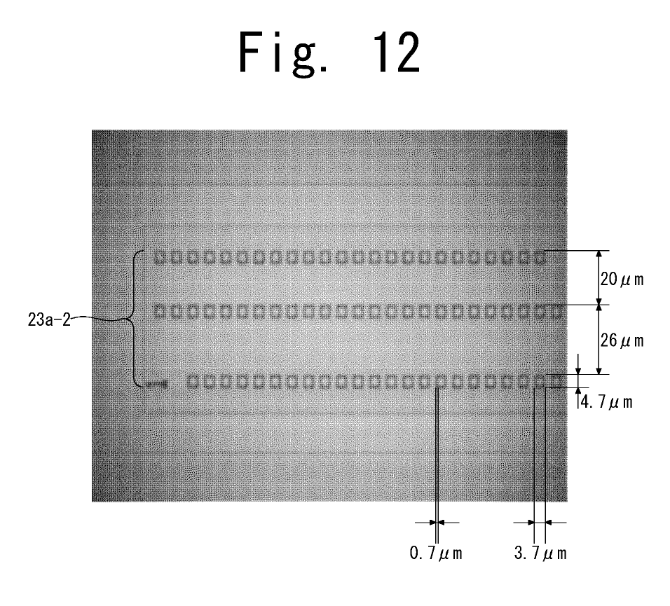

Now, a mechanism of crack development in relation to the width d of the alignment tungsten plugs 23a will be described with reference to the drawings. FIG. 11 is a photograph taken of a semiconductor substrate, in which alignment mark 123a- 1 which do not satisfy the condition of d≦1.25 s as disclosed in this embodiment and alignment marks 23a-1 which satisfy the condition of d≦1.25 s as disclosed in this embodiment are formed, and which was heated at a temperature of 800° C. in an oxygen atmosphere for 30 minutes. FIG. 12 is a photograph taken of a semiconductor substrate, in which alignment mark 23a-2 which satisfy the condition of d≦1.25 s as disclosed in this embodiment are formed, and which was heated at a temperature of 800° C. in an oxygen atmosphere for 30 minutes. In both FIG. 11 and FIG. 12, the device size s is set to 0.64 μm. In either case, removal of the tungsten film 3A was done using the etch-back method as described above with respect to the manufacturing method, and the conditions of the etch-back process used here are those described above. In FIG. 11, with respect to the alignment mark 123a-1 on the left side, the shape thereof is a square of which the width d is 1.0 μm (i.e. about 1.6 times the device size s) and each length of the outer circumferential side is 5.0 μm, and the interval Px in the lengthwise direction is 20 μm. On the other hand, in FIG. 11, with respect to the alignment mark 23a-1 on the right side, the shape thereof is a square of which the width d is 0.6 μm (i.e. 0.94 times the device size s) and each length of the outer circumferential side is 4.6 μm, and the interval Px in the lengthwise direction is 20 μm. In FIG. 12, with respect to the alignment mark 23a-2, the shape thereof is a rectangle of which the width d is 0.7 μm (i.e. 1.09 times the device size s), the length of the outer circumferential side in the lengthwise direction is 4.7 μm, and the length of the outer circumferential side in the crosswise direction is 3.7 μm. Moreover, in FIG. 12, the interval Px in the lengthwise direction on the upper side is 20 μm (i.e. Px=20 μm), and the interval Px in the lengthwise direction on the lower side is 26 μm (i.e. Px=26 μm).

As can be seen from FIG. 11 and FIG. 12, when the width d of the alignment tungsten plug 23a is no greater than 1.25 times the device size s (the case of the right side in FIG. 11 and the case of FIG. 12), no crack is formed on the upper layers (i.e. the silicon oxide film 4, the silicon nitride film 5 and the silicon oxide film 6) of the alignment tungsten plugs 23a in the semiconductor device after being heated in an oxygen atmosphere. In other words, the semiconductor device is formed appropriately. On the other hand, when the width d of the alignment tungsten plug 23a is greater than 1.25 times the device size s (the case of the left side in FIG. 11), cracks are formed on the upper layers (i.e. the silicon oxide film 4, the silicon nitride film 5 and the silicon oxide film 6) of the alignment tungsten plugs 23a. Here, it is obvious that there are defects in the semiconductor device.

As described above, according to this embodiment of the present invention, by forming the alignment tungsten plug 23a such that its width d becomes no greater than 1.25 times the device size s, it is possible to manufacture a semiconductor device which does not produce any defects even after the heating treatment in an oxygen atmosphere.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2005-37588. The entire disclosures of Japanese Patent Application No. 2005-37588 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

What is claimed is:

1. A method of forming an alignment mark for specifying an optimum exposing position, comprising:
preparing a substrate having a semiconductor element and an insulation film covering the semiconductor element;
forming a resist pattern having a first opening on the insulation film, the first opening having a first width which is 1.25 times or less than a second width of a contact plug which is electrically connected to the semiconductor element;
forming a second opening with the first width in the insulation film by etching the insulation film using the resist pattern as a mask;
removing the resist pattern;
forming a first conductive film on the insulation film and inside the second opening by depositing a metal over the insulation film; and
removing the first conductive film on the insulation film while leaving a portion of the first conductive film inside the second opening as an alignment mark.

2. The method of forming an alignment mark according to claim 1, further comprising:
forming a third opening in the insulation film by etching the insulation film using the resist pattern as a mask while forming the second opening in the insulation film, the resist pattern further having a fourth opening for forming the third opening, widths of the third and fourth openings being the second width; and
forming a second conductive film inside the fourth opening by depositing a metal over the insulation film while forming the first conductive film on the insulation film and inside the second opening, wherein
the first conductive film on the insulation film is removed while leaving the second conductive film inside the third opening as the contact plug.

3. The method of forming an alignment mark according to claim 1, wherein
the shape of the first opening is a line or a framed rectangle.

4. The method of forming an alignment mark according to claim 1, wherein
the metal is tungsten.

5. A method of manufacturing a semiconductor device comprising:
preparing a substrate having a semiconductor element and an insulation film covering the semiconductor element;
forming a resist pattern having a first opening on the insulation film, the first opening having a first width which is 1.25 times or less than the second width of a contact plug which is electrically connected to the semiconductor element;
forming a second opening with the first width in the insulation film by etching the insulation film using the resist pattern as a mask;
removing the resist pattern;
forming a first conductive film on the insulation film and inside the second opening by depositing a metal over the insulating film; and
removing the first conductive film on the insulation film while leaving a portion of the first conductive film inside the second opening as an alignment mark.

6. The method of manufacturing a semiconductor device according to claim 5, further comprising:
forming a silicon nitride film over the insulation film.

7. The method of manufacturing a semiconductor device according to claim 5, further comprising:
forming a first silicon oxide film on the insulation film;
forming a silicon nitride film on the first silicon oxide film; and
forming a second silicon oxide film on the silicon nitride film.

8. The method of manufacturing a semiconductor device according to claim 5, further comprising:
forming a third opening in the insulation film by etching the insulation film using the resist pattern as a mask while forming the second opening in the insulation film, the resist pattern further having a fourth opening for forming the third opening, width of the third and fourth openings being the second width; and
forming a second conductive film inside the fourth opening by depositing a metal over the insulation film while forming the first conductive film on the insulation film and inside the second opening, wherein
the first conductive film on the insulation film is removed while leaving the second conductive film inside the third opening as the contact plug.
